(19) United States
(12) Patent Application Publication
(10) Pub. No.: US 2024/0016068 A1
(43) Pub. Date: Jan. 11, 2024

(54) SUPERCONDUCTING QUANTUM CIRCUIT

(71) Applicants: NEC Corporation, Tokyo (JP); NATIONAL INSTITUTE OF ADVANCED INDUSTRIAL SCIENCE AND TECHNOLOGY, Tokyo (JP)

(72) Inventors: Yohei KAWAKAMI, Tokyo (JP); Yoshiro URADE, Tokyo (JP); Yoshihito HASHIMOTO, Tokyo (JP); Tsuyoshi YAMAMOTO, Tokyo (JP)

(73) Assignees: NEC Corporation, Tokyo (JP); NATIONAL INSTITUTE OF ADVANCED INDUSTRIAL SCIENCE AND TECHNOLOGY, Tokyo (JP)

(21) Appl. No.: 18/341,092

(22) Filed: Jun. 26, 2023

(30) Foreign Application Priority Data
Jul. 5, 2022 (JP) 2022-108087

(51) Int. Cl. H10N 60/12; H10N 60/80; G06N 10/40

(52) U.S. Cl. CPC H10N 60/12; H10N 60/805; G06N 10/40

(57) ABSTRACT

A superconducting quantum circuit includes: a first resonator having a superconducting quantum interference device and a capacitor that forms a closed loop together with the superconducting quantum interference device; and a control line being connected to a first control port and magnetically coupled to the superconducting quantum interference device, wherein the control line includes at least a first line having a characteristic impedance that indicates a first impedance value, and a second line being provided closer to a portion magnetically coupled to the superconducting quantum interference device than the first line and having a characteristic impedance that indicates a second impedance value being different from the first impedance value.

### INCORPORATION BY REFERENCE

This application is based upon and claims the benefit of priority from Japanese patent application No. 2022-108087, filed on Jul. 5, 2022, the disclosure of which is incorporated herein in its entirety by reference.

### TECHNICAL FIELD

The present invention relates to a superconducting quantum circuit.

### BACKGROUND ART

In a quantum information processing circuit, a resonator is used in various applications such as a quantum circuit (a circuit that generates qubits), a coupler, and an amplifier. Energy stored in the resonator being lost is referred to as a loss, which is equivalent to an error in the quantum information processing circuit, and therefore required to be suppressed. Resonator losses include an internal loss caused by a resistive component of a resonator element and the like, and an external loss caused by a port being intentionally attached to the resonator in order to couple the resonator with an external environment. Suppressing the external loss is relatively easy since such suppression is achievable through adjustment of parameters such as coupling strength. However, the internal loss is often caused by a factor not intended by a designer, such as dielectric loss of a material and coupling to a floating mode, thus suppressing the internal loss is one of important problems regarding the resonator being used in the quantum information processing circuit.

Japanese Patent No. 6530326 discloses a typical configuration of a variable frequency resonator including a port (control port) to which a control signal for externally controlling a resonance frequency is supplied.

In a quantum information processing circuit using superconductivity, a variable frequency resonator capable of externally controlling a resonance frequency is used for a quantum circuit generating a qubit and a parametric amplifier being one kind of an amplifier. A variable frequency resonator disclosed in Japanese Patent No. 6530326 includes a resonator constituted of a capacitor and a superconducting quantum interference device (SQUID), and a control line being connected to a control port to which a control signal is supplied from the outside and magnetically coupled to the superconducting quantum interference device. In this variable frequency resonator, the resonator oscillates at an oscillation frequency according to a control signal supplied to the control port from the outside. However, this variable frequency resonator has a problem that an oscillation signal of the resonator leaks to the control port, resulting in an increase in the internal loss.

### SUMMARY

An example object of the present disclosure is to provide a superconducting quantum circuit that solves the above-described problem.

In one example aspect, a superconducting quantum circuit includes: a first resonator configured to have a superconducting quantum interference device and a capacitor that forms a closed loop together with the superconducting quantum interference device; and a control line configured to be connected to a first control port and magnetically coupled to the superconducting quantum interference device, wherein the control line includes at least a first line configured to have a characteristic impedance that indicates a first impedance value and a second line configured to be provided closer to a portion magnetically coupled to the superconducting quantum interference device than the first line and have a characteristic impedance that indicates a second impedance value being different from the first impedance value.

### BRIEF DESCRIPTION OF DRAWINGS

The above and other aspects, features, and advantages of the present disclosure will become more apparent from the following description of certain example embodiments when taken in conjunction with the accompanying drawings, in which:

FIG. 1 is a circuit diagram illustrating a configuration example of a variable frequency resonator according to a first example embodiment;

FIG. 2 is a circuit diagram illustrating a configuration example of a variable frequency resonator for simulation implementation according to the first example embodiment;

FIG. 3 is a diagram illustrating the relationship between an excitation frequency of a resonator 10 and an absolute value of a physical quantity S21 in the variable frequency resonator illustrated in FIG. 2;

FIG. 4 is a diagram illustrating the relationship between the length of the control line L13 and a power transmitted from the resonator 10 to a control port in the variable frequency resonator illustrated in FIG. 2;

FIG. 5 is a diagram illustrating one example of a layout of the variable frequency resonator illustrated in FIG. 2;

FIG. 6 is a circuit diagram illustrating a configuration example of a variable frequency resonator according to a second example embodiment;

FIG. 7 is a circuit diagram illustrating a modification example of the variable frequency resonator illustrated in FIG. 6;

FIG. 8 is a circuit diagram illustrating a configuration example of a variable frequency resonator according to a third example embodiment;

FIG. 9 is a circuit diagram illustrating a configuration example of a variable frequency resonator of a conceptual stage;

FIG. 10 is a circuit diagram illustrating a configuration example of a variable frequency resonator for simulation implementation of a conceptual stage; and

FIG. 11 is a diagram illustrating the relationship between an excitation frequency of a resonator 50 and an absolute value of a physical quantity S21 in the variable frequency resonator illustrated in FIG. 10.

### EXAMPLE EMBODIMENT

Hereinafter, example embodiments will be described with reference to the drawings. Note that, since the drawings are simplified, the technical scope of the example embodiments is not to be construed narrowly based on the description of the drawings. The same elements are denoted by the same reference numbers, and redundant description thereof will be omitted.

In the following example embodiments, when necessary for convenience, description will be made by dividing the example embodiments into a plurality of sections or example embodiments. However, unless otherwise specified, the sections or example embodiments are not unrelated to one another, and one of the sections or example embodiment is a modification example, an application example, a detailed description, a supplementary description, or the like related to a part or all of another of the sections or example embodiments. In addition, in the following example embodiments, when referring to the number and the like (including the number, numerical value, amount, range, and the like) of an element, unless otherwise specified or clearly limited to a specific number in principle, the number is not limited to the specific number, and may be the specific number or more or less.

Further, in the following example embodiments, constituent elements (including operation steps and the like) are not necessarily indispensable, unless otherwise specified or considered to be essential in principle. Similarly, in the following example embodiments, when referring to a shape, a positional relationship, and the like of a constituent element, unless otherwise specified or considered to be obviously inappropriate in principle, substantially close or similar shapes and the like are assumed to be included. This also applies to the above-mentioned numbers and the like (including the number, numerical value, amount, range, and the like).

Hereinafter, quantum computing refers to a region in which data is manipulated using quantum mechanical phenomena (qubits). Quantum mechanical phenomena include superposition of a plurality of states (a quantum variable having a plurality of different states at the same time), entanglement (a state in which a plurality of quantum variables are related to one another regardless of space or time), and the like. A quantum chip is provided with a quantum circuit that generates a qubit.

### [Preliminary Study by the Inventors]

Before describing the variable frequency resonator (superconducting quantum circuit) according to the first example embodiment, contents studied in advance by the inventors will be described.

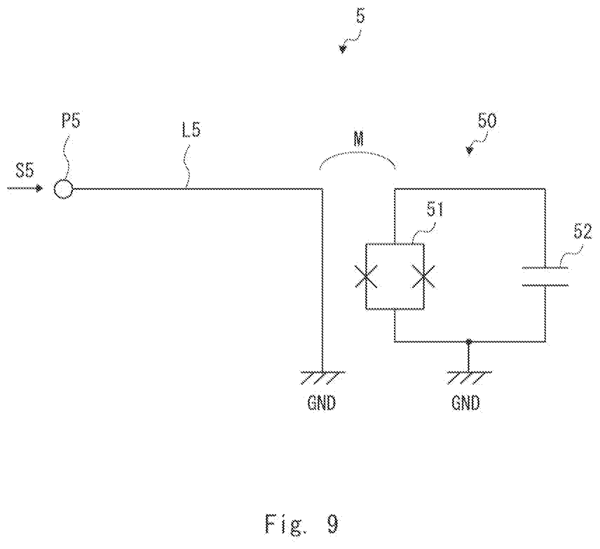

FIG. 9 is a circuit diagram illustrating a configuration example of a variable frequency resonator 5. The variable frequency resonator 5 is a superconducting quantum circuit being used, in a quantum information processing circuit using superconductivity, for example, for a quantum circuit that generates a qubit, a parametric amplifier being one kind of an amplifier, or the like.

As illustrated in FIG. 9, the variable frequency resonator 5 includes a resonator 50 and a control line L5. The resonator 50 includes a SQUID 51 and a capacitor 52 that forms a closed loop together with the SQUID 51. One end of the control line L5 is connected to a control port P5, and the other end of the control line L5 is connected (terminated) to ground GND. A direct current or high-frequency control signal S5 is supplied from the outside to the control port P5. The control line L5 is magnetically coupled to the SQUID 51. Note that M in the figure represents a state of being magnetically coupled. In the variable frequency resonator 5, the resonator 50 oscillates at a frequency according to the control signal S5 supplied from the outside to the control port P5. The variable frequency resonator 5 may be used in, for example, a transmon, or may be used in a Josephson parametric oscillator or a Josephson parametric amplifier.

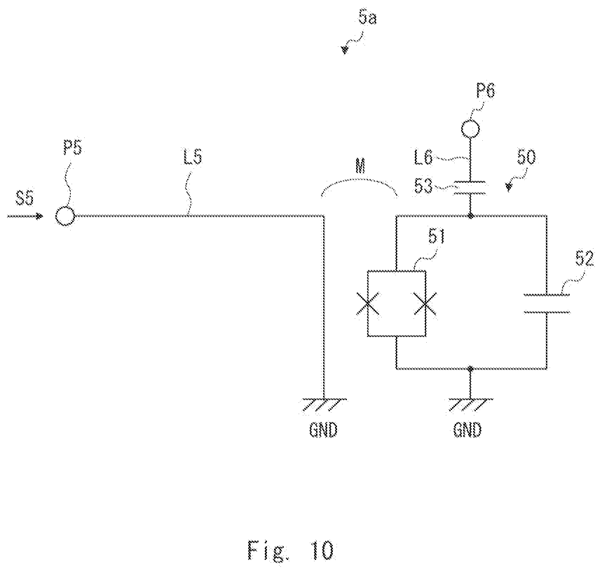

FIG. 10 is a circuit diagram illustrating a configuration example of a variable frequency resonator 5a used in a simulation. As compared with the variable frequency resonator 5 (illustrated in FIG. 9), the variable frequency resonator 5a further includes an input/output line L6 for inputting and outputting a signal used for a simulation, in order to quantitatively evaluate, through the simulation, excitation energy leaking from a resonator 50 to a control port P5. One end of the input/output line L6 is connected to an input/output port P6 through which a signal is input/output to/from the outside. The other end of the input/output line L6 is connected to the resonator 50. A capacitor 53 is provided on the input/output line L6. That is, the input/output port P6 and the resonator 50 are coupled by the input/output line L6 via the capacitor 53. Other configurations of the variable frequency resonator 5a are similar to those of the variable frequency resonator 5, and thus description thereof will be omitted.

In the variable frequency resonator 5a, the resonator 50 oscillates at a frequency according to a control signal S5 supplied from the outside to the control port P5. More specifically, in the variable frequency resonator 5a, the control signal S5 is supplied from the outside to the control port P5, and a magnetic field having an intensity according to the control signal S5 is applied to a SQUID 51, thereby the inductance of the SQUID 51 is changed, and the resonance frequency of the resonator 50 is adjusted.

Herein, assuming that the inductance of the SQUID 51 in a certain magnetic field is L and the capacitance of the capacitor 52 is C, the resonance frequency or of the variable frequency resonator 5a is expressed by the following equation (1).

ωr=(LC)\hat{ }(−½) (1):

An internal loss of the variable frequency resonator 5a is generated when an input signal is supplied from the outside to the input/output port P6 and a part of the input signal is transmitted to the control port P5 via the control line L5. Such a transmission can be quantitatively evaluated by calculating a physical quantity called S21 by using an electromagnetic field simulation. The physical quantity S21 is one of S parameters, and, when a first port and a second port are present, the square of the absolute value of the physical quantity S21 indicates a ratio of the energy transmitted to the second port to the energy supplied to the first port. In the variable frequency resonator 5a, the input/output port P6 corresponds to the first port, and the control port P5 corresponds to the second port. Hereinafter, the internal loss of the variable frequency resonator 5 is investigated by performing a simulation by using the variable frequency resonator 5a.

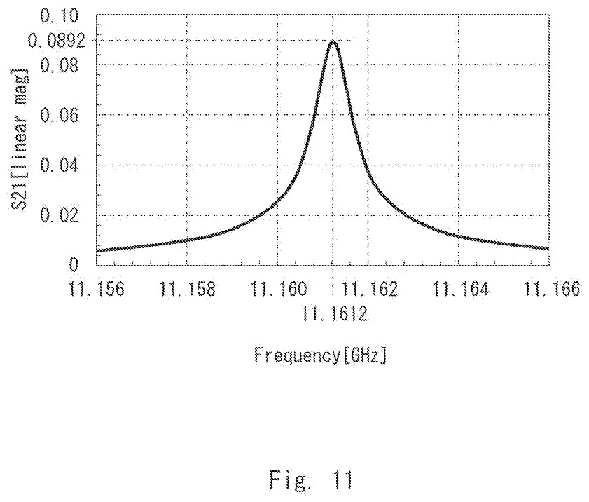

FIG. 11 is a diagram illustrating a simulation result of the variable frequency resonator 5a. In FIG. 11, the relationship between the excitation frequency of the resonator 50 and the absolute value of the physical quantity S21 in the variable frequency resonator 5a is illustrated. In FIG. 11, the horizontal axis represents the excitation frequency of the resonator 50, and the vertical axis represents the absolute value of the physical quantity S21.

Referring to FIG. 11, at 11.1612 GHz, which is the resonance frequency of the resonator 50, the absolute value of the physical quantity S21 indicates 0.0892 being the maximum value. This means that, for example, when power of 1000 mW (milliwatts) is supplied to the input/output port P6, power of approximately 8.0 mW (=1000 mW×(0.0892)\hat{ }2) is transmitted to the control port P5. At this time, the remaining power of approximately 992 mW is reflected to the input/output port P6. That is, the power of 1000 mW supplied to the input/output port P6 is divided into the power reflected to the input/output port P6 and the power transmitted to the control port P5. Therefore, it is not necessary to consider the leakage of energy to the ground GND where the control line L5 is terminated.

As described above, in the variable frequency resonator 5, suppression of the transmission of energy from the resonator 50 to the control port P5, that is, the internal loss of the variable frequency resonator 5, is required. In order to satisfy this requirement, the present inventors have found variable frequency resonators 1 to 3 as described below.

### First Example Embodiment

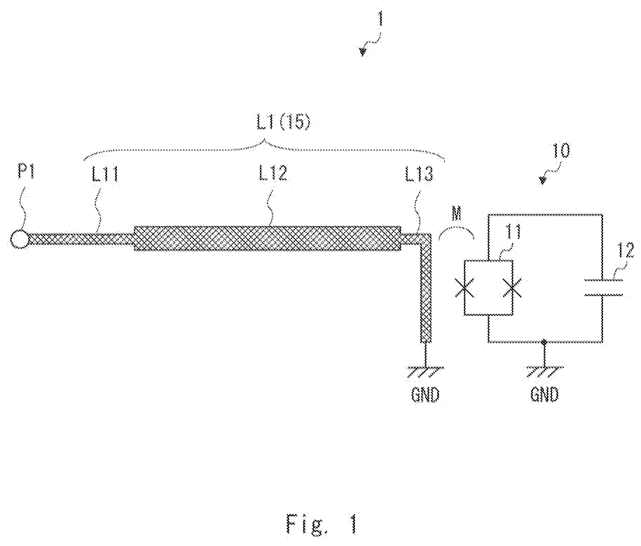

FIG. 1 is a circuit diagram illustrating a configuration example of a variable frequency resonator 1 according to a first example embodiment. The variable frequency resonator 1 is a superconducting quantum circuit being used, in a quantum information processing circuit using superconductivity, for example, for a quantum circuit that generates a qubit, a parametric amplifier being one kind of an amplifier, or the like.

As illustrated in FIG. 1, the variable frequency resonator 1 includes a resonator 10 and a control line L1. The resonator 10 includes a SQUID 11 and a capacitor 12 that forms a closed loop together with the SQUID 11. One end of the control line L1 is connected to a control port P1, and the other end of the control line L1 is connected (terminated) to ground GND. The control port P1 is externally supplied with, for example, a direct current or high-frequency control signal S1. The control line L1 is magnetically coupled to the SQUID 11. Note that M in the figure represents a state of being magnetically coupled. In the variable frequency resonator 1, the resonator 10 oscillates at a frequency according to the control signal S1 supplied from the outside to the control port P1.

Herein, the control line L1 includes control lines L11, L12, L13 constituting a step-impedance resonator 15. The control lines L11, L12, L13 are provided in order from the control port P1 to the ground GOD in the control line L1. Specifically, the control line L11 is provided on a side closest to the control port P1 in the control line L1. The control line L12 is provided in the control line L1 in such a way as to be continuous with the control line L11 on the side closer to a portion magnetically coupled to the SQUID 11 than the control line L11. The control line L13 is provided in the control line L1, in such a way as to be continuous with the control line L12, on the side closer to the portion magnetically coupled to the SQUID 11 than the control line L12 (in other words, on the side farthest from the control port P1). In the present example embodiment, the control line L13 and the SQUID 11 are magnetically coupled to each other.

The characteristic impedance of each of the control lines L11 and L13 indicates Z0. The characteristic impedance of the control line L12 indicates Z1 being different from Z0.

In the variable frequency resonator 1, the resonator 10 and the step impedance resonator 15 are fabricated, for example, on a semiconductor chip by use of microfabrication. The control port P1 is connected to a high-frequency cable by a connector (not illustrated) outside the variable frequency resonator 1. The high-frequency cable is connected to, for example, an electronic circuit (control circuit) that outputs a control signal S1. Herein, in order to suppress high-frequency reflection loss, the characteristic impedance of the high-frequency cable and the characteristic impedance of the control line L11 being connected to the control port P1 are preferably the same value. In general, the characteristic impedance of a high frequency cable is often 50 ohms (Ω) or 75Ω. Therefore, in the present example embodiment, a case where the characteristic impedance of the high-frequency cable is 50Ω, and accordingly the characteristic impedance of the control lines L11 and L13 is also 50Ω, will be described as an example. That is, in the present example embodiment, a case where Z0=50Ω will be described as an example.

It is preferable that the difference between the characteristic impedance of the control line L12 and the characteristic impedance of the control lines L11 and L13 be large as possible. That is, the larger the difference between Z0 and Z1 is, the more preferable. For example, |Z0−Z1| is preferably 20Ω or more, and more preferably 30Ω or more. Therefore, in the present example embodiment, a case where the characteristic impedance of the control lines L11 and L13 is 50Ω, whereas the characteristic impedance of the control line L12 is 20Ω will be described as an example. That is, in the present example embodiment, a case where Z0=50Ω and Z1=20Ω will be described as an example. However, Z0 and Z1 may be set to any values as long as Z0 and Z1 are different from each other.

Herein, the resonance frequency of the step impedance resonator 15 is determined by the length of the control line L12. The resonance frequency of the step impedance resonator 15 includes, in addition to the resonance frequency of a fundamental mode having the lowest frequency, a resonance frequency of the higher-order mode. The resonance frequency of the fundamental mode of the step impedance resonator 15 is such a frequency that the length of the control line L12 is half of the wavelength. In the following description, the step impedance resonator 15 including the control lines L1, L12, L13 may also be referred to as a half-wavelength step impedance resonator.

Further, in the variable frequency resonator 1, the resonance frequencies of the fundamental mode and the higher-order mode of the step impedance resonator 15 are different from the resonance frequency of the resonator 10. Note that, in the following description, the resonance frequencies of the fundamental mode and the higher-order mode of the step impedance resonator 15 may be collectively referred to simply as the resonance frequency of the step impedance resonator 15. Accordingly, the step impedance resonator 15 functions as a filter that reflects the resonance energy of the variable frequency resonator 1 at the end portion of the control line L12. Therefore, the step impedance resonator 15 is capable of preventing the transmission of the resonance energy of the resonator 10 to the control port P1.

Further, by designing in such a way that the transmittance of the step impedance resonator 15 is lowest at the resonance frequency or of the resonator 10, it is possible to enhance the function of the step impedance resonator 15 as a filter. For this purpose, the resonance frequency of the step impedance resonator 15 is preferably twice +/−10%, and most preferably twice, of the resonance frequency of the resonator 10. In other words, the resonance frequency of the step impedance resonator 15 is preferably equal to or greater than 0.9 times the twice of the resonance frequency of the resonator 10 and equal to or less than 1.1 times the twice of the resonance frequency of the resonator 10, and most preferably twice the resonance frequency of the resonator 10.

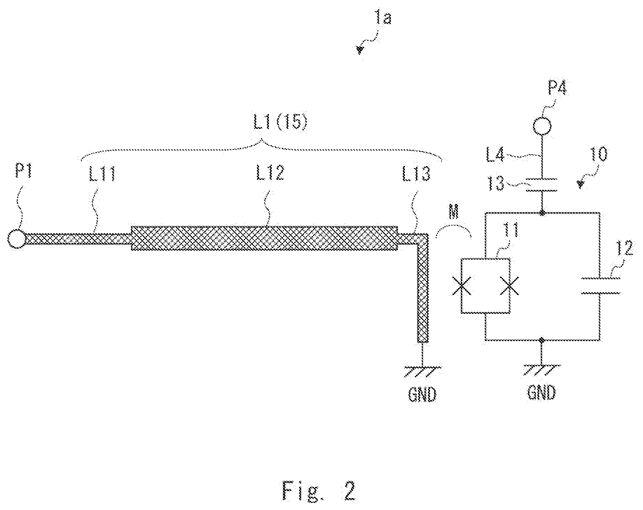

FIG. 2 is a circuit diagram illustrating a configuration example of a variable frequency resonator 1a for simulation implementation. As compared with the variable frequency resonator 1 (illustrated in FIG. 1), the variable frequency resonator 1a further includes an input/output line L4 for inputting and outputting a signal being used for the simulation in order to quantitatively evaluate the excitation energy leaking from the resonator 10 to the control port P1 through the simulation. One end of the input/output line L4 is connected to an input/output port P4 through which a signal is input/output to/from the outside. The other end of the input/output line L4 is connected to the resonator 10. A capacitor 13 is provided on the input/output line L4. That is, the input/output port P4 and the resonator 10 are coupled by the input/output line L4 via the capacitor 13. The other configurations of the variable frequency resonator 1a are similar to those of the variable frequency resonator 1, and thus description thereof will be omitted. Hereinafter, the internal loss of the variable frequency resonator 1 is investigated by performing a simulation using the variable frequency resonator 1a.

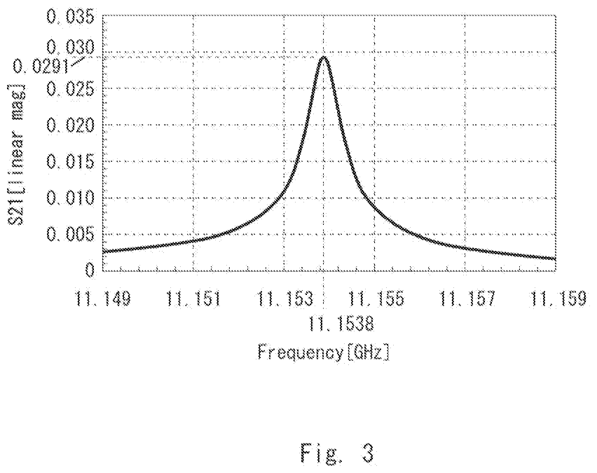

FIG. 3 is a diagram illustrating a simulation result of the variable frequency resonator 1a. In FIG. 3, the relationship between the excitation frequency of the resonator 10 and the absolute value of the physical quantity S21 in the variable frequency resonator 1a is illustrated. In FIG. 3, the horizontal axis represents the excitation frequency of the resonator 10, and the vertical axis represents the absolute value of the physical quantity S21. Note that, the physical quantity S21 is one of the S parameters, and, when the first port and the second port are present, the square of the absolute value of the physical quantity S21 indicates the ratio of the energy transmitted to the second port to the energy supplied to the first port. In the variable frequency resonator 1a, the input/output port P4 corresponds to the first port, and the control port P1 corresponds to the second port.

Referring to FIG. 3, at 11.1538 GHz, which is the resonance frequency of the resonator 10, the absolute value of the physical quantity S21 indicates 0.0291 being the maximum value. This means that, for example, when power of 1000 mW is supplied to the input/output port P4, power of approximately 0.8 mW (=1000 mW×(0.0291)\hat{ }2) is transmitted to the control port P1. Meanwhile, in the variable frequency resonator 5a, when power of 1000 mW is supplied to the input/output port P6, power of approximately 8.0 mW is transmitted to the control port P5. Therefore, as compared with the variable frequency resonator 5a, the variable frequency resonator 1a can more significantly suppress transmission (leakage) of energy from the resonator 10 to the control port P1.

Note that, in order to increase the degree of integration of the circuit on which the variable frequency resonator 1a is mounted, it is preferable that the circuit scale of the variable frequency resonator 1a be as small as possible.

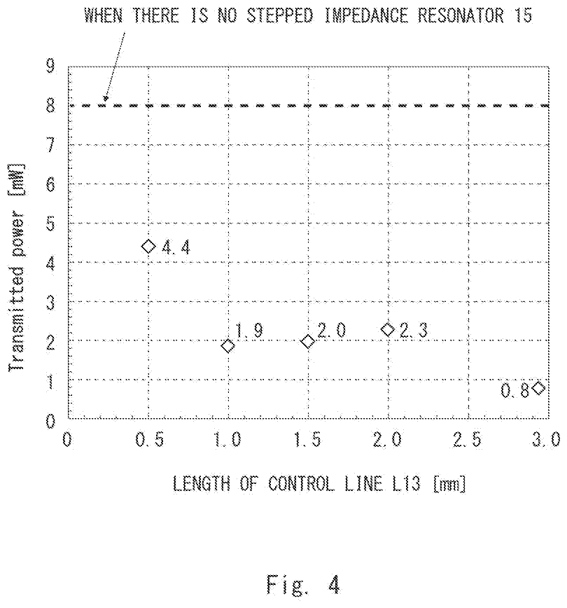

Therefore, first, it is considered to shorten the length of the control line L13 as much as possible. Specifically, an electromagnetic field simulation is performed on the variable frequency resonator 1a having different lengths of the control line L13. FIG. 4 is a diagram illustrating a relationship between the length of the control line L13 and the power being transmitted to the control port P1. As illustrated in FIG. 4, as the control line L13 becomes longer, the transmission of power from the resonator 10 to the control port P1, that is, the internal loss of the variable frequency resonator 1a, is further suppressed. In particular, in order to suppress the transmission of power from the resonator 10 to the control port P1 to equal to or less than 30% as compared with the variable frequency resonator 5a which does not include the step impedance resonator 15, the length of the control line L13 needs to be equal to or more than 1.0 mm. The length of 1.0 mm is approximately one-twelfth of the wavelength for the resonance frequency (11.1538 GHz) of the resonator 10. Therefore, it can be said that the length of the control line L13 is preferably equal to or more than one-twelfth of the wavelength for the resonance frequency of the resonator 10.

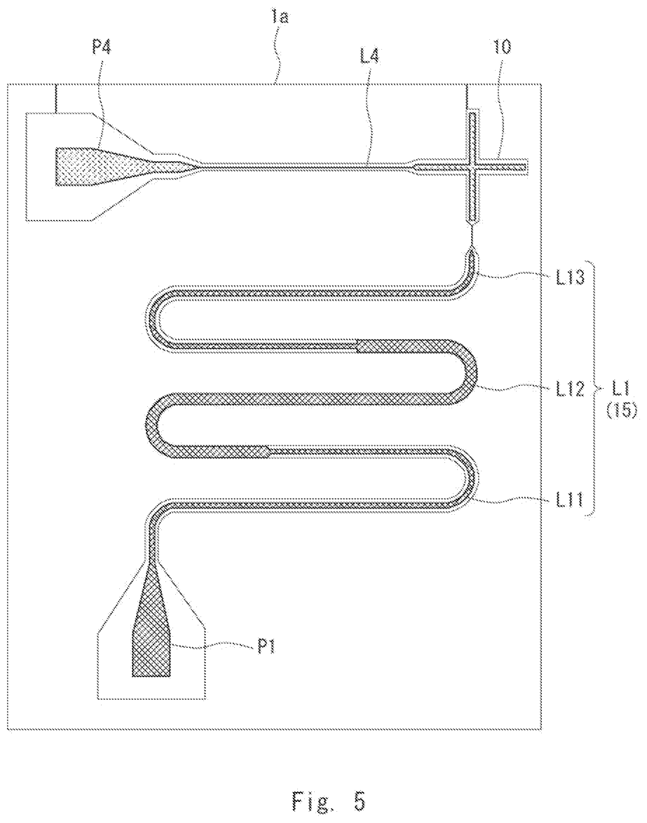

Next, it is considered to place the control line L1 in an area as small as possible. FIG. 5 is a diagram illustrating one example of a layout of the variable frequency resonator 1a. In the example of FIG. 5, the control line L1 (in other words, the step impedance resonator 15) is arranged in such a way as to be partially curved. Such a layout structure is called a meander-type layout structure. Note that, the layout structure of the control line L1 is not limited to the meander type illustrated in FIG. 5, and may be another layout structure being curved in any manner. As described above, by arranging the control line L1 in a partially curved manner, the circuit scale of the variable frequency resonator 1a can be reduced.

Further, in a structure of the variable frequency resonator 1 having a relatively long control line L1, resonances different from the intended resonances may appear in the chip. In order to prevent such a phenomenon, it is preferable to provide an air bridge formed in such a way as to surround the control line L1. An air bridge is a structure in which both surfaces of the ground separated by the control line L1 are electrically connected through aerial crosslinking by using a superconductor. The effectiveness of such a structure is described, for example, in Japanese Patent Nos. 6437607 and 6749382. However, the conductor is not limited to an air bridge, and may be any conductor that electrically connects both surfaces of the ground.

As described above, the variable frequency resonator 1 according to the present example embodiment can suppress the transmission of energy from the resonator 10 to the control port P1, that is, the internal loss, by providing the step impedance resonator 15 in the control line L1.

Note that, the variable frequency resonator 1 may be used for, for example, a transmon, or may be used for a Josephson parametric oscillator or a Josephson parametric amplifier. An increase in an internal Q value in the Josephson parametric amplifier leads to an increase in the amplification efficiency (quantum efficiency) of a signal. However, in a case where the variable frequency resonator 1 is applied to the transmon, when the high-frequency control signal S1 is used, it is necessary to calibrate in advance the high-frequency control signal S1 supplied from the outside to the control port P1 in consideration of the step impedance resonator 15 being included in the control line L1. That is, in a case where the variable frequency resonator 1 is applied to the transmon, it is necessary to calibrate in advance the control signal S1 before passing through the step impedance resonator 15, in such a way that the control signal S1 after passing through the step impedance resonator 15 becomes a desired rectangular wave.

### Second Example Embodiment

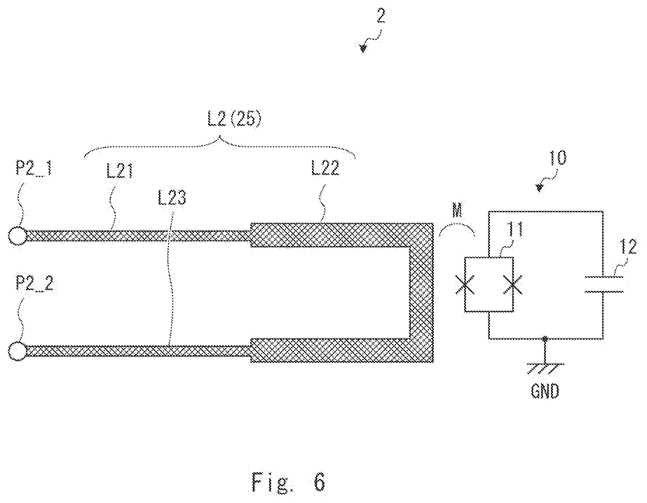

FIG. 6 is a circuit diagram illustrating a configuration example of a variable frequency resonator 2 according to a second example embodiment. The variable frequency resonator 2 is a superconducting quantum circuit being used, in a quantum information processing circuit using superconductivity, particularly for a Josephson parametric oscillator and a Josephson parametric amplifier.

As compared with the variable frequency resonator 1 (illustrated in FIG. 1), the variable frequency resonator 2 includes a control line L2 instead of the control line L1. One end of the control line L2 is connected to the control port P2_1, and the other end of the control line L2 is connected to the control port P2_2. At least one of the control ports P2_1 and P2_2 is supplied with a direct current or high-frequency control signal S2 from the outside. The control line L2 is magnetically coupled to the SQUID 11. Note that M in the figure represents a state of being magnetically coupled. In the variable frequency resonator 2, the resonator 10 oscillates at a frequency according to the control signal S2 supplied from the outside to at least one of the control ports P2_1 and P2_2.

Herein, the control line L2 includes control lines L21, L22, L23 constituting a step impedance resonator 25. The step impedance resonator 25 corresponds to the step impedance resonator 15, and the control lines L21, L22, L23 correspond to the control lines L11, L12, L13, respectively. The control lines L21, L22, L23 are provided in order from the control port P2_1 to the control port P2_2 in the control line L2. Herein, in the present example embodiment, the vicinity of the center of the control line L22 and the SQUID 11 are magnetically coupled to each other. Other structures of the variable frequency resonator 2 are similar to those of the variable frequency resonator 1, and thus description thereof will be omitted.

In the step impedance resonator 25 having a half-wavelength, the current becomes the largest in the vicinity of the center of the control line L22, and the amplification effect of the control signal S2 can be expected, thereby the power of the control signal S2 supplied from at least one of the control ports P2_1 and P2_2 can be set low by magnetically coupling the vicinity of the center of the control line L22 and the SQUID 11.

### (Modification Example of Variable Frequency Resonator 2)

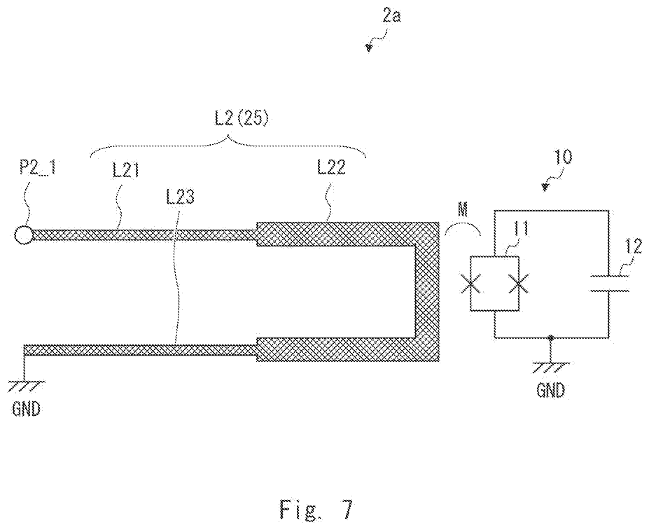

FIG. 7 is a circuit diagram illustrating a modified example of the variable frequency resonator 2 (illustrated in FIG. 6) as a variable frequency resonator 2a. In the variable frequency resonator 2a, the other end of the control line L2 is connected (terminated) to the ground GND instead of the control port P2_2. Other structures of the variable frequency resonator 2a are similar to those of the variable frequency resonator 2, and thus description thereof will be omitted. Thereby, the variable frequency resonator 2a can simplify the structure more than the variable frequency resonator 2. Further, in the variable frequency resonator 2a, since the number of control ports is less than that of the variable frequency resonator 2, it is possible to reduce the number of high-frequency wires connected to the control port.

### Third Example Embodiment

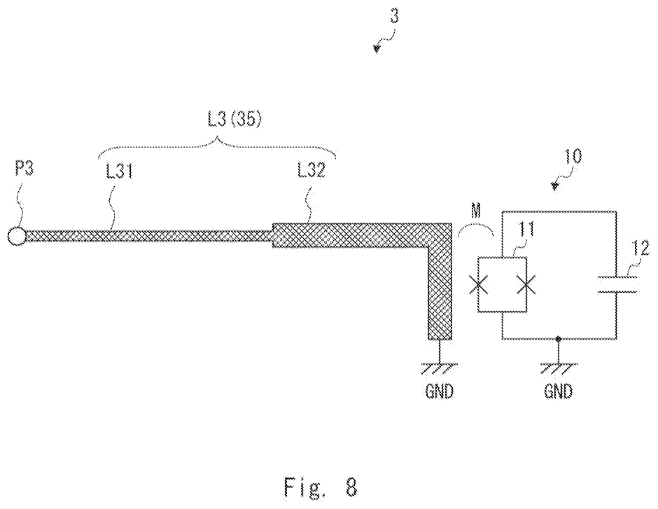

FIG. 8 is a circuit diagram illustrating a configuration example of a variable frequency resonator 3 according to a third example embodiment. As compared with the variable frequency resonator 1 (illustrated in FIG. 1), the variable frequency resonator 3 includes a control line L3 instead of the control line L1. One end of the control line L3 is connected to a control port P3, and the other end of the control line L3 is connected (terminated) to ground GND. The control port P3 is externally supplied with, for example, a direct current or high-frequency control signal S3.

The control line L3 includes control lines L31, L32 constituting a step impedance resonator 35. The step impedance resonator 35 corresponds to the step impedance resonator 15, and the control lines L31, L32 correspond to the control lines L11, L12, respectively. In the step impedance resonator 35, there is no control line corresponding to the control line L13. The control lines L31, L32 are provided in order from the control port P3 to the ground GND in the control line L3. In the present example embodiment, the control line L32 and the SQUID 11 are magnetically coupled to each other. In the variable frequency resonator 3, the resonator 10 oscillates at a frequency according to the control signal S3 supplied from the outside to the control port P3.

Herein, the resonance frequency of a fundamental mode of the step impedance resonator 35 is such a frequency that the length of the control line L32 is one-fourth of the wavelength. In the following description, the step impedance resonator 35 including the control lines L31, L32 is also referred to as a step impedance resonator having a quarter wavelength. Meanwhile, the resonance frequency of the fundamental mode of the step impedance resonator 15 is such a frequency that the length of the control line L12 is half the wavelength. That is, in the step impedance resonator 35, in order to set the resonance frequency of the fundamental mode, the length of the control line L32 can be made shorter than the length of the control line L12 of the step impedance resonator 15. Therefore, the variable frequency resonator 3 can suppress the circuit scale further than the variable frequency resonator 1.

While the example embodiments of the present disclosure have been described in detail with reference to the drawings, the specific configuration is not limited to the above, and various design changes and the like may be made without departing from the spirit and scope of the present disclosure.

The first to third embodiments can be combined as desirable by one of ordinary skill in the art.

While the disclosure has been particularly shown and described with reference to embodiments thereof, the disclosure is not limited to these embodiments. It will be understood by those of ordinary skill in the art that various changes in form and details may be made therein without departing from the spirit and scope of the present disclosure as defined by the claims.

The whole or part of the example embodiments described above can be described as, but not limited to, the following supplementary notes.

### (Supplementary Note 1)

A superconducting quantum circuit including:
a first resonator configured to have a superconducting quantum interference device and a capacitor that forms a closed loop together with the superconducting quantum interference device; and
a control line configured to be connected to a first control port and magnetically coupled to the superconducting quantum interference device,
   wherein the control line includes at least:
a first line configured to have a characteristic impedance that indicates a first impedance value; and
a second line configured to be provided closer to a portion magnetically coupled to the superconducting quantum interference device than the first line and have a characteristic impedance that indicates a second impedance value being different from the first impedance value.

### (Supplementary Note 2)

The superconducting quantum circuit according to Supplementary note 1, wherein a first resonance frequency being a frequency of resonance of the first resonator that is generated by supplying a control signal from outside to the first control port, and a second resonance frequency being a resonance frequency of a second resonator constituted of the first line and the second line are different from each other.

### (Supplementary Note 3)

The superconducting quantum circuit according to Supplementary note 2, wherein the second resonance frequency is equal to or more than 0.9 times twice of the first resonance frequency and equal to or less than 1.1 times twice of the first resonance frequency.

### (Supplementary Note 4)

The superconducting quantum circuit according to any one of Supplementary notes 1 to 3, wherein
one end of the control line is connected to the first control port, and another end of the control line is connected to ground, and
the second line is magnetically coupled to the superconducting quantum interference device.

### (Supplementary Note 5)

The superconducting quantum circuit according to Supplementary note 1, wherein the control line further includes a third line configured to be provided in such a way that the second line is sandwiched between the third line and the first line, and have a characteristic impedance that indicates the first impedance value.

### (Supplementary Note 6)

The superconducting quantum circuit according to Supplementary note 5, wherein a first resonance frequency being a frequency of resonance of the first resonator that is generated by supplying a control signal from outside to the first control port, and a second resonance frequency being a resonance frequency of a second resonator constituted of the first line, the second line, and the third line are different from each other.

### (Supplementary Note 7)

The superconducting quantum circuit according to Supplementary note 6, wherein the second resonance frequency is equal to or more than 0.9 times twice of the first resonance frequency and equal to or less than 1.1 times twice of the first resonance frequency.

### (Supplementary Note 8)

The superconducting quantum circuit according to any one of Supplementary notes 5 to 7, wherein the third line is configured to have a length of one-twelfth of a wavelength with respect to a first resonance frequency being a frequency of resonance of the first resonator that is generated by supplying a control signal from outside to the first control port.

### (Supplementary Note 9)

The superconducting quantum circuit according to any one of Supplementary notes 5 to 8, wherein
one end of the control line is connected to the first control port, and another end of the control line is connected to ground, and
the third line is magnetically coupled to the superconducting quantum interference device.

### (Supplementary Note 10)

The superconducting quantum circuit according to any one of Supplementary notes 5 to 8, wherein
one end of the control line is connected to the first control port, and another end of the control line is connected to ground or a second control port, and
the second line is magnetically coupled to the superconducting quantum interference device.

### (Supplementary Note 11)

The superconducting quantum circuit according to Supplementary note 10, wherein the first resonator is used as a Josephson parametric oscillator or a Josephson parametric amplifier.

### (Supplementary Note 12)

The superconducting quantum circuit according to any one of Supplementary notes 1 to 11, wherein the first impedance value is at least one of 50Ω and 75Ω.

### (Supplementary Note 13)

The superconducting quantum circuit according to any one of Supplementary notes 1 to 12, wherein a difference between the second impedance value and the first impedance value is 20Ω or more.

### (Supplementary Note 14)

The superconducting quantum circuit according to any one of Supplementary notes 1 to 13, wherein the control line has a curved portion being partially curved.

### (Supplementary Note 15)

The superconducting quantum circuit according to any one of Supplementary notes 1 to 14, further comprising an air bridge structure configured to be formed in such a way as to surround the control line.

An example advantage according to the above-described embodiments is that it is possible to provide a superconducting quantum circuit capable of suppressing internal loss.

What is claimed is:

1. A superconducting quantum circuit comprising:
a first resonator configured to have a superconducting quantum interference device and a capacitor that forms a closed loop together with the superconducting quantum interference device; and
a control line configured to be connected to a first control port and magnetically coupled to the superconducting quantum interference device,
wherein the control line includes at least:
a first line configured to have a characteristic impedance that indicates a first impedance value; and
a second line configured to be provided closer to a portion magnetically coupled to the superconducting quantum interference device than the first line and have a characteristic impedance that indicates a second impedance value being different from the first impedance value.

2. The superconducting quantum circuit according to claim 1, wherein a first resonance frequency being a frequency of resonance of the first resonator that is generated by supplying a control signal from outside to the first control port, and a second resonance frequency being a resonance frequency of a second resonator constituted of the first line and the second line are different from each other.

3. The superconducting quantum circuit according to claim 2, wherein the second resonance frequency is equal to or more than 0.9 times twice of the first resonance frequency and equal to or less than 1.1 times twice of the first resonance frequency.

4. The superconducting quantum circuit according to claim 1, wherein
one end of the control line is connected to the first control port, and another end of the control line is connected to ground, and
the second line is magnetically coupled to the superconducting quantum interference device.

5. The superconducting quantum circuit according to claim 1, wherein the control line further includes a third line configured to be provided in such a way that the second line is sandwiched between the third line and the first line, and have a characteristic impedance that indicates the first impedance value.

6. The superconducting quantum circuit according to claim 5, wherein a first resonance frequency being a frequency of resonance of the first resonator that is generated by supplying a control signal from outside to the first control port, and a second resonance frequency being a resonance frequency of a second resonator constituted of the first line, the second line, and the third line are different from each other.

7. The superconducting quantum circuit according to claim 6, wherein the second resonance frequency is equal to or more than 0.9 times twice of the first resonance frequency and equal to or less than 1.1 times twice of the first resonance frequency.

8. The superconducting quantum circuit according to claim 5, wherein the third line is configured to have a length of one-twelfth of a wavelength with respect to a first resonance frequency being a frequency of resonance of the first resonator that is generated by supplying a control signal from outside to the first control port.

9. The superconducting quantum circuit according to claim 5, wherein
one end of the control line is connected to the first control port, and another end of the control line is connected to ground, and
the third line is magnetically coupled to the superconducting quantum interference device.

10. The superconducting quantum circuit according to claim 5, wherein
one end of the control line is connected to the first control port, and another end of the control line is connected to ground or a second control port, and
the second line is magnetically coupled to the superconducting quantum interference device.

11. The superconducting quantum circuit according to claim 10, wherein the first resonator is used as a Josephson parametric oscillator or a Josephson parametric amplifier.

12. The superconducting quantum circuit according to claim 1, wherein the first impedance value is at least one of 50Ω and 75Ω.

13. The superconducting quantum circuit according to claim 1, wherein a difference between the second impedance value and the first impedance value is 20Ω or more.

14. The superconducting quantum circuit according to claim 1, wherein the control line has a curved portion being partially curved.

15. The superconducting quantum circuit according to claim 1, further comprising an air bridge structure configured to be formed in such a way as to surround the control line.
